(19) United States
(12) Patent Application Publication
(10) Pub. No.: US 2024/0258412 A1
(43) Pub. Date: Aug. 1, 2024

(54) METHOD FOR MANUFACTURING SEMICONDUCTOR APPARATUS

(71) Applicant: FUJI ELECTRIC CO., LTD., Kanagawa (JP)

(72) Inventors: Toshiki SUZUKI, Matsumoto-city (JP); Toshiyuki MATSUI, Matsumoto-city (JP); Tatsuya NAITO, Matsumoto-city (JP); Kazuki KAMIMURA, Matsumoto-city (JP)

(21) Appl. No.: 18/515,259

(22) Filed: Nov. 21, 2023

(30) Foreign Application Priority Data
Jan. 30, 2023 (JP) 2023-011570

(51) Int. Cl. H01L 29/739; H01L 29/06; H01L 29/861

(52) U.S. Cl. CPC H01L 29/7397; H01L 29/0607; H01L 29/0696; H01L 29/861

(57) ABSTRACT

Provided is a method for manufacturing a semiconductor apparatus including: a transistor portion provided in a semiconductor substrate of a first conductivity type and including a base region of a second conductivity type; a diode portion provided in the substrate and including an anode region of the second conductivity type; and a first trench contact provided in the diode portion on a front surface side of the substrate, the method comprising: acquiring a condition of trade-off between a reverse recovery loss of the diode portion and a forward voltage of the diode portion; deciding a target characteristic required for the semiconductor apparatus; determining whether a first depth of the trench contact according to the characteristic satisfies a diode condition which is a condition for realizing the characteristic, of the condition of trade-off; and manufacturing the semiconductor apparatus in which a depth of the trench contact is the first depth.

The contents of the following patent application(s) are incorporated herein by reference: NO. 2023-011570 filed in JP on Jan. 30, 2023

### BACKGROUND

### 1. Technical Field

The present invention relates to a method for manufacturing a semiconductor apparatus.

### 2. Related Art

Patent Document 1 describes “a semiconductor apparatus which can suppress snapback of an FWD element”.

### PRIOR ART DOCUMENT

### Patent Document

Patent Document 1: Japanese Patent Application Publication No. 2012-156564
Patent Document 2: Japanese Patent Application Publication No. 2016-154218
Patent Document 3: Japanese Patent Application Publication No. 2017-41601
Patent Document 4: Japanese Patent Application Publication No. 2021-144998

### BRIEF DESCRIPTION OF THE DRAWINGS

FIG. 1A shows an example of an upper surface of a semiconductor apparatus 100.

FIG. 1B shows an example of a cross section a-a′ in FIG. 1A.

FIG. 1C shows an example of doping concentration distribution in a cross section b-b′ in FIG. 1B.

FIG. 2 shows an example of a condition of trade-off between a reverse recovery loss Err of a diode portion 80 and a forward voltage Vf of the diode portion 80.

FIG. 3 shows an example of a threshold condition for a threshold voltage Vth of a transistor portion 70 with respect to a depth of a second trench contact 67.

FIG. 4A shows a modified example of the cross section a-a′ in FIG. 1A.

FIG. 4B shows an example of doping concentration distribution in a cross section c-c′ in

FIG. 4A.

FIG. 5A shows a modified example of the cross section a-a′ in FIG. 1A.

FIG. 5B shows an example of doping concentration distribution in a cross section d-d′ in

FIG. 5A.

FIG. 6A shows a modified example of the cross section a-a′ in FIG. 1A.

FIG. 6B shows an example of doping concentration distribution in a cross section e-e′ in

FIG. 6A.

FIG. 7A shows an example of a relationship between a condition of trade-off, and a depth of a first trench contact 66 and a doping concentration of an anode region 13.

FIG. 7B shows a modified example of a relationship between a condition of trade-off, and a depth of the first trench contact 66 and a doping concentration of the anode region 13.

FIG. 8A is a flowchart showing an example of a method for manufacturing the semiconductor apparatus 100.

FIG. 8B is a flowchart showing an example of a step S120 in FIG. 8A.

FIG. 9A is flowchart showing a modified example of a method for manufacturing the semiconductor apparatus 100.

FIG. 9B is a flowchart showing an example of a step S300 in FIG. 9A.

FIG. 9C is a flowchart showing a modified example of the step S300 in FIG. 9A.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to a solution of the invention.

In the present specification, one side in a direction parallel to a depth direction of a semiconductor substrate is referred to as “upper” and the other side is referred to as “lower”. One surface of two principal surfaces of a substrate, a layer or some other member is referred to as an upper surface, and the other surface is referred to as a lower surface. “Upper” and “lower” directions are not limited to a direction of gravity, or a direction in which a semiconductor apparatus is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to variability in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type. In addition, in the present specification, a description of a P−− type or an N−− type means a lower doping concentration than that of the P-type or the N-type.

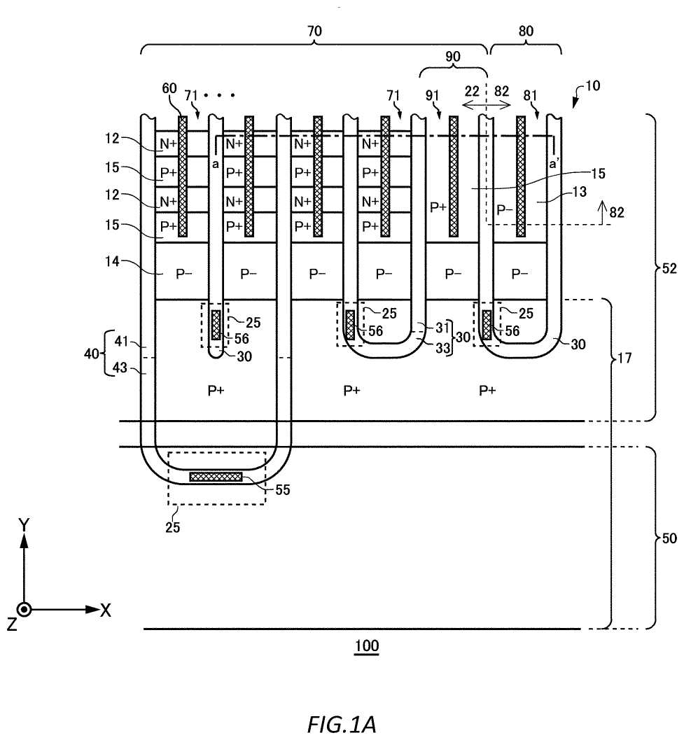

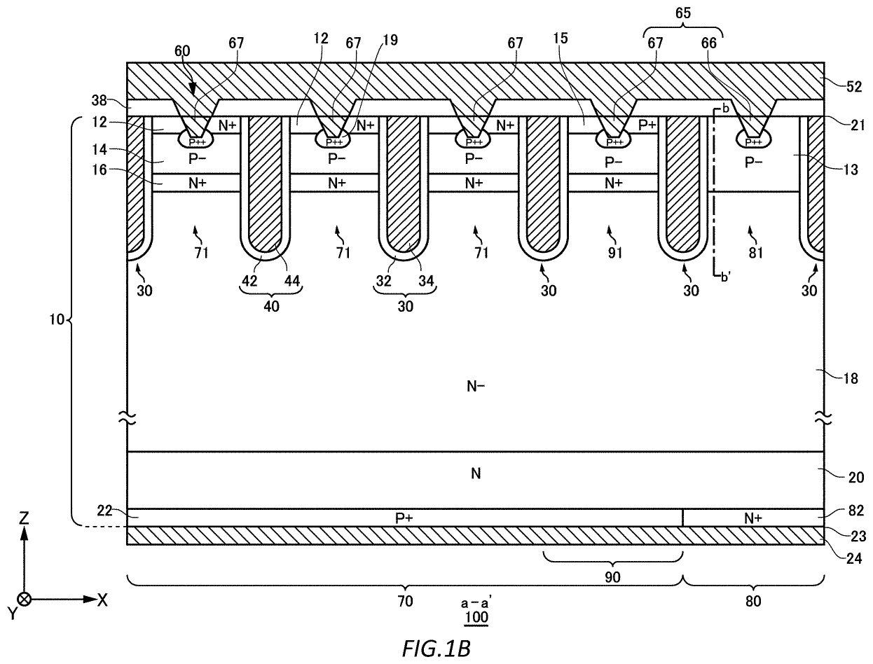

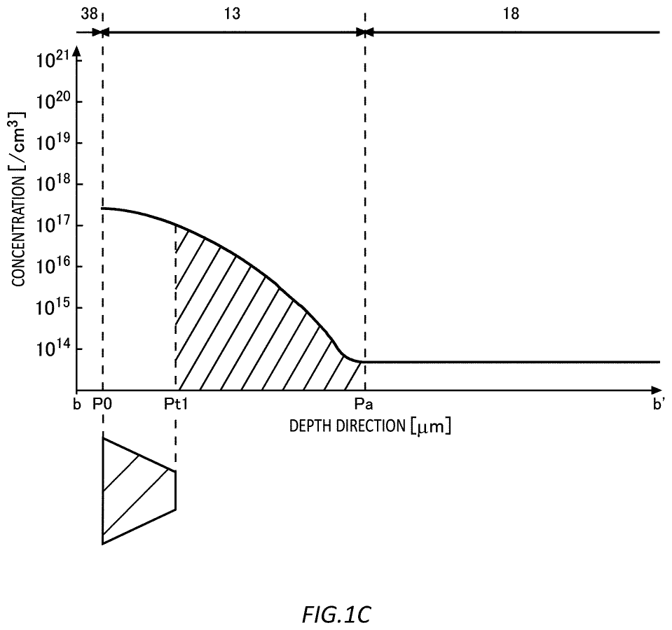

FIG. 1A shows an example of an upper surface of a semiconductor apparatus 100. The semiconductor apparatus 100 in the present example is a semiconductor chip having a transistor portion 70 and a diode portion 80. The diode portion 80 is formed adjacently to the transistor portion 70. For example, the semiconductor apparatus 100 is a reverse conducting insulated gate bipolar transistor (RC-IGBT). FIG. 1A shows an upper surface of the chip around an end portion of the chip is shown, and omits other regions.

In addition, while FIG. 1A shows an active region of the semiconductor substrate in the semiconductor apparatus 100, the semiconductor apparatus 100 may have an edge termination structure portion enclosing the active region. The active region refers to a region through which a current flows if the semiconductor apparatus 100 is controlled to be ON. The edge termination structure portion reduces electric field strength on an upper surface side of the semiconductor substrate. The edge termination structure portion has, for example, a guard ring, a field plate, a RESURF, and a structure which is a combination thereof.

The semiconductor substrate 10 is a substrate formed of a semiconductor material of a first conductivity type. The semiconductor substrate 10 may be a silicon substrate, a silicon carbide substrate, or a nitride semiconductor substrate or the like such as a gallium nitride semiconductor substrate. The semiconductor substrate 10 in the present example is a silicon substrate. It should be noted that, when merely referred to as the top view in the present specification, it means that the semiconductor substrate 10 is viewed from the upper surface side.

The transistor portion 70 is a region obtained by projecting a collector region 22 provided on a back surface 23 side of a semiconductor substrate 10 onto an upper surface of the semiconductor substrate 10. The collector region 22 will be described later. The transistor portion 70 includes a transistor such as an IGBT. In the present example, the transistor portion 70 is an IGBT. It should be noted that the transistor portion 70 may be another transistor such as a MOSFET.

The diode portion 80 is a region obtained by projecting a cathode region 82 provided on the back surface 23 side of the semiconductor substrate 10 onto the upper surface of the semiconductor substrate 10. The cathode region 82 will be described later. The diode portion 80 includes a diode such as a free wheel diode (FWD) provided adjacently to the transistor portion 70 at the upper surface of the semiconductor substrate 10.

The semiconductor apparatus 100 in the present example includes a gate trench portion 40, a dummy trench portion 30, an emitter region 12, an anode region 13, a base region 14, a contact region 15, and a well region 17 at a front surface 21 of the semiconductor substrate 10. The front surface 21 will be described later. In addition, the semiconductor apparatus 100 in the present example includes an emitter electrode 52 and a gate metal layer 50 which are provided above the front surface 21 of the semiconductor substrate 10.

The emitter electrode 52 is provided above the gate trench portion 40, the dummy trench portion 30, the emitter region 12, the anode region 13, the base region 14, the contact region 15, and the well region 17. In addition, the gate metal layer 50 is provided above the gate trench portion 40 and the well region 17.

The emitter electrode 52 and the gate metal layer 50 are formed of a material including metal. At least a partial region of the emitter electrode 52 may be formed of metal such as aluminum (Al) or a metal alloy such as an aluminum-silicon alloy (AlSi) or an aluminum-silicon-copper alloy (AlSiCu). At least a partial region of the gate metal layer 50 may be formed of metal such as aluminum (Al) or a metal alloy such as an aluminum-silicon alloy (AlSi) or an aluminum-silicon-copper alloy (AlSiCu). The emitter electrode 52 and the gate metal layer 50 may have a barrier metal formed of titanium, titanium compound, or the like under the region formed of aluminum or the like. The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted in FIG. 1A. A contact hole 55, a contact hole 56, and a contact hole 60 are provided through the interlayer dielectric film 38.

The contact hole 55 connects the gate metal layer 50 to a gate conductive portion in the transistor portions 70. A plug metal layer formed of tungsten or the like may be formed in the contact hole 55.

The contact hole 56 connects the emitter electrode 52 to a dummy conductive portion in the dummy trench portion 30. A plug metal layer formed of tungsten or the like may be formed in the contact hole 56.

The connection portion 25 electrically connects a front surface side electrode such as the emitter electrode 52 or the gate metal layer 50 to the semiconductor substrate 10. In an example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with an impurity. The connection portion 25 in the present example is formed of polysilicon doped with an N type impurity (N+). The connection portion 25 is provided above the front surface 21 of the semiconductor substrate 10 via a dielectric film such as an oxide film, or the like.

The gate trench portions 40 are examples of a plurality of trench portions extending in a predetermined extending direction on a front surface 21 side of the semiconductor substrate 10. The gate trench portions 40 are arrayed at predetermined intervals along a predetermined array direction (the X axis direction in the present example). The gate trench portion 40 in the present example may have: two extending parts 41 that extend along an extending direction (the Y axis direction in the present example) which is parallel to the front surface 21 of the semiconductor substrate 10 and which is perpendicular to the array direction; and a connecting part 43 that connects the two extending parts 41.

At least part of the connecting part 43 is preferably formed in a curved shape. Connecting end portions of the two extending parts 41 of the gate trench portions 40 can reduce electric field strength at the end portions of the extending parts 41. At the connecting part 43 of the gate trench portion 40, the gate metal layer 50 may be connected to the gate conductive portion.

The dummy trench portions 30 are examples of the plurality of trench portions extending in the predetermined extending direction on the front surface 21 side of the semiconductor substrate 10. The dummy trench portion 30 is a trench portion electrically connected to the emitter electrode 52. The dummy trench portions 30 are arrayed, similarly to the gate trench portion 40, at predetermined intervals along a predetermined array direction (the X axis direction in the present example). The dummy trench portion 30 in the present example has an I shape at the front surface 21 of the semiconductor substrate 10, but it may have, similarly to the gate trench portion 40, a U shape at the front surface 21 of the semiconductor substrate 10. That is, the dummy trench portion 30 may have two extending parts 31 which extend along the extending direction and a connecting part 33 which connects the two extending parts.

The transistor portion 70 in the present example has a structure in which two gate trench portions 40 and two dummy trench portions 30 are repetitively arrayed. That is, the transistor portion 70 in the present example has the gate trench portions 40 and the dummy trench portions 30 at a ratio of 1:1. For example, the transistor portion 70 has one dummy trench portion 30 between two extending parts 41.

It should be noted that the ratio of the gate trench portions 40 and the dummy trench portions 30 is not limited to that in the present example. The ratio of the gate trench portions 40 and the dummy trench portions 30 may be 2:3, or may be 2:4. In addition, the transistor portion 70 does not need to have the dummy trench portions 30 with all the trench portions being the gate trench portions 40.

In the transistor portion 70, a boundary adjacent to the diode portion 80 is provided with an intermediate region 90 on the surface of which the emitter region 12 is not formed. In addition, in the transistor portion 70, a plurality of dummy trench portions 30 may be continuously arrayed in a part adjacent to the intermediate region 90. The dummy trench portion 30 formed in the part adjacent to the intermediate region 90 may also have the extending parts 31 and the connecting part 33.

The number of the dummy trench portions 30 continuously arrayed at the boundary with the diode portion 80 may be greater than the number of the dummy trench portions 30 continuously arrayed inside the transistor portion 70 apart from the diode portion 80. In the example of FIG. 1A, the dummy trench portion 30 having the connecting part 33 and the extending parts 31 is provided in the transistor portion 70 at the boundary with the diode portion 80 (that is, the intermediate region 90 and the part adjacent to the intermediate region 90). In the example of FIG. 1A, the two extending parts 31 connected via the connecting part 33 are continuously arrayed in the array direction perpendicular to the extending direction of the extending parts 31. Meanwhile, inside the transistor portion 70, the extending parts 41 of the gate trench portions 40 and the dummy trench portions 30 in a linear shape are alternately arrayed one by one.

The well region 17 is a region of a second conductivity type which is provided on the front surface 21 side of the semiconductor substrate 10 relative to a drift region 18 which will be described later. The well region 17 is an example of a well region provided in an edge side of the semiconductor apparatus 100. The well region 17 is of the P+ type as an example. The well region 17 is formed within a predetermined range from an end portion of the active region on a side where the gate metal layer 50 is provided. A diffusion depth of the well region 17 may be deeper than depths of the gate trench portion 40 and the dummy trench portion 30. Partial regions of the gate trench portion 40 and the dummy trench portion 30 on a gate metal layer 50 side are formed in the well region 17. The bottoms at ends of the gate trench portion 40 and the dummy trench portion 30 in the extending direction may be covered with the well region 17.

The contact hole 60 is formed above each region of the emitter region 12 and the contact region 15 in the transistor portion 70. The contact hole 60 is provided above the anode region 13 in the diode portion 80. The contact hole 60 is provided above the contact region 15 in the intermediate region 90. No contact holes 60 are provided above the well regions 17 provided at both ends in the Y axis direction. In this manner, one or more contact holes 60 are formed in the interlayer dielectric film. The one or more contact holes 60 may be provided extending in the extending direction.

The mesa portion 71 is provided in direct contact with at least one of the dummy trench portion 30 or the gate trench portion 40 in the transistor portion 70. The mesa portion 71 includes the well region 17, the emitter region 12, the base region 14, and the contact region 15 at the front surface 21 of the semiconductor substrate 10. In the mesa portion 71, the emitter regions 12 and the contact regions 15 are alternately provided in the extending direction.

The mesa portion 91 is provided in the intermediate region 90. The mesa portion 91 includes the contact region 15 at the front surface 21 of the semiconductor substrate 10. The mesa portion 91 in the present example includes the base region 14 and the well region 17 on a negative side of the Y axis direction.

The mesa portion 81 is provided in a region sandwiched between the dummy trench portions 30 adjacent to each other in the diode portion 80. The mesa portion 81 has the anode region 13 at the front surface 21 of the semiconductor substrate 10. The mesa portion 81 in the present example has the base region 14 and the well region 17 on the negative side of the Y axis direction.

The base region 14 is a region of the second conductivity type which is provided on the front surface 21 side of the semiconductor substrate 10. The base region 14 is of the P-type as an example. The base regions 14 may be provided at both end portions of the mesa portion 71, the mesa portion 81, and the mesa portion 91 in the Y axis direction, at the front surface 21 of the semiconductor substrate 10. It should be noted that FIG. 1A shows only one end portion of the base region 14 in the Y axis direction.

The emitter region 12 is a region of the first conductivity type which is provided above the base region 14. The emitter region 12 is of the N+ type as an example. The emitter region 12 in the present example is provided in contact with the gate trench portion 40 at the front surface 21 of the mesa portion 71. The emitter region 12 may be provided extending in the X axis direction from one to the other of two trench portions sandwiching the mesa portion 71. The emitter region 12 is also provided below the contact hole 60.

In addition, the emitter region 12 mayor may not be in contact with the dummy trench portion 30. The emitter region 12 in the present example is in contact with the dummy trench portion 30.

The contact region 15 is a region of a second conductivity type, which is provided above the base region 14 and has a higher doping concentration than the base region 14. The contact region 15 in the present example is of the P+ type as an example. The contact region 15 in the present example is provided at the front surface 21 of the mesa portion 71 and the mesa portion 91. The contact region 15 may be provided in the X axis direction from one to the other of the two trench portions sandwiching the mesa portion 71. The contact region 15 mayor may not be in contact with the gate trench portion 40 or the dummy trench portion 30. The contact region 15 in the present example is in contact with the dummy trench portion 30 and the gate trench portion 40. The contact region 15 is also provided below the contact hole 60.

The anode region 13 is a region of the second conductivity type provided at the front surface 21 of the semiconductor substrate 10. The anode region 13 is of the P-type as an example. The anode region 13 is provided in contact with the dummy trench portion 30 at the front surface 21 of the mesa portion 81. The anode region 13 may be provided extending in the X axis direction from one to the other of two trench portions sandwiching the mesa portion 81. The anode region 13 is also provided below the contact hole 60.

A doping concentration of the anode region may be 1e12/cm² or higher and 1e14/cm² or lower. A doping concentration of the anode region 13 may be higher than a doping concentration of the base region 14, may be the same as the doping concentration of the base region 14, or may be lower than the doping concentration of the base region 14. The doping concentration of the anode region 13 in the present example is the same as the doping concentration of the base region 14. If the doping concentration of the anode region 13 is the same as the doping concentration of the base region 14, the anode region 13 and the base region 14 can be formed by the same ion implantation process.

The emitter region 12 is provided in the mesa portion 71, but does not need to be provided in the mesa portion 81 and the mesa portion 91. The contact region 15 is provided in the mesa portion 71 and the mesa portion 91, but does not need to be provided in the mesa portion 81. The anode region 13 is provided in the mesa portion 81, but does not need to be provided in the mesa portion 71 and the mesa portion 91.

In the transistor portion 70, the collector region 22 of the P+ type is formed at a back surface 23 of the semiconductor substrate 10. In FIG. 1A, a region where the collector region 22 is formed is indicated by a dotted line.

In the diode portion 80, the cathode region 82 of the N+ type is formed at the back surface 23 of the semiconductor substrate 10. In FIG. 1A, a region where the cathode region 82 is formed is indicated by a dotted line. The collector region 22 of P+ type may be formed in a region where the cathode region 82 is not formed in a region adjacent to a lower surface of the semiconductor substrate.

FIG. 1B shows an example of a cross section a-a′ in FIG. 1A. The cross section a-a′ is an XZ plane which passes through the emitter region 12 in the transistor portion 70. In the cross section a-a′, the semiconductor apparatus 100 in the present example has the semiconductor substrate 10, the interlayer dielectric film 38, the emitter electrode 52, and a collector electrode 24. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N-type as an example. The drift region 18 may be a region that has remained without other doping regions being formed in the semiconductor substrate 10. That is, a doping concentration of the drift region 18 may be a doping concentration of the semiconductor substrate 10.

A buffer region 20 is a region of the first conductivity type which is provided on the back surface 23 side of the semiconductor substrate 10 relative to the drift region 18. The buffer region 20 in the present example is of the N type as an example. A doping concentration of the buffer region 20 is higher than the doping concentration of the drift region 18. The buffer region 20 may function as a field stop layer which prevents a depletion layer expanding from a lower surface side of the base region 14 from reaching the collector region 22 of the second conductivity type.

The collector region 22 is provided below the buffer region 20 in the transistor portion 70. The collector region 22 has the second conductivity type. The collector region 22 in the present example is of the P+ type as an example.

The cathode region 82 is provided below the buffer region 20 in the diode portion 80. A boundary between the collector region 22 and the cathode region 82 is a boundary between the transistor portion 70 and the diode portion 80. That is, the collector region 22 is provided below the intermediate region 90 in the present example.

The collector electrode 24 is formed on the back surface 23 of the semiconductor substrate 10. The collector electrode 24 is formed of a conductive material such as metal.

The base region 14 is provided above the drift region 18 in the transistor portion 70. The base region 14 is provided in contact with the gate trench portion 40. The base region 14 may be provided in contact with the dummy trench portion 30.

The emitter region 12 is provided above the base region 14 in the mesa portion 71. The emitter region 12 is provided between the base region 14 and the front surface 21 in the mesa portion 71. The emitter region 12 is provided in contact with the gate trench portion 40 in the mesa portion 71. The emitter region 12 mayor may not be in contact with the dummy trench portion 30 in the mesa portion 71.

The contact region 15 is provided above the base region 14 in the mesa portion 91. The contact region 15 is provided in contact with the dummy trench portion 30 in the mesa portion 91.

An accumulation region 16 is a region of the first conductivity type which is provided on the front surface 21 side of the semiconductor substrate 10 relative to the drift region 18 in the transistor portion 70. The accumulation region 16 in the present example is of the N+ type as an example. It should be noted that the accumulation region 16 does not need to be provided. The accumulation region 16 in the present example is not provided in the diode portion 80, but the accumulation region 16 may be provided in the diode portion 80.

In addition, the accumulation region 16 is provided in contact with the gate trench portion 40. The accumulation region 16 mayor may not be in contact with the dummy trench portion 30. A doping concentration of the accumulation region 16 is higher than the doping concentration of the drift region 18.

The anode region 13 is provided above the drift region 18 in the mesa portion 81. The anode region 13 is provided in contact with the dummy trench portion 30.

One or more gate trench portions 40 and one or more dummy trench portions 30 are provided at the front surface 21. Each trench portion is provided from the front surface 21 to the drift region 18. In a region provided with at least any one of the emitter region 12, the anode region 13, the base region 14, the contact region 15, or the accumulation region 16, each trench portion also penetrates these regions to reach the drift region 18. A configuration in which the trench portions penetrate these regions is not limited to what is manufactured in an order of forming these regions and then forming the trench portions. The configuration in which the trench portions penetrate these regions also includes what is manufactured in an order of forming the trench portions and then forming these regions between the trench portions.

The gate trench portion 40 has a gate trench, a gate dielectric film 42, and a gate conductive portion 44 which are formed at the front surface 21. The gate dielectric film 42 is formed covering an inner wall of the gate trench. The gate dielectric film 42 may be formed by oxidizing or nitriding a semiconductor on the inner wall of the gate trench. The gate conductive portion 44 is formed farther inward in the gate trench than the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 on the front surface 21.

The gate conductive portion 44 includes a region facing the base region 14 that is adjacent to the gate conductive portion 44 on the mesa portion 71 side with the gate dielectric film 42 interposed therebetween, in the depth direction of the semiconductor substrate 10. When a predetermined voltage is applied to the gate conductive portion 44, a channel due to an electron inversion layer is formed in a surface layer of a boundary surface which is of the base region 14 and which is in contact with the gate trench.

The dummy trench portion 30 may have the same structure as that of the gate trench portion 40. The dummy trench portion 30 has a dummy trench, a dummy dielectric film 32, and a dummy conductive portion 34 which are formed on the front surface 21 side. The dummy dielectric film 32 is formed covering an inner wall of the dummy trench. The dummy conductive portion 34 is formed in the dummy trench, and is formed farther inward than the dummy dielectric film 32. The dummy dielectric film 32 insulates the dummy conductive portion 34 from the semiconductor substrate 10. The dummy trench portion 30 is covered by the interlayer dielectric film 38 on the front surface 21.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with the one or more contact holes 60 for electrically connecting the emitter electrode 52 and the semiconductor substrate 10. Similarly, the contact hole 55 and the contact hole 56 may be provided penetrating the interlayer dielectric film 38. The interlayer dielectric film 38 may be a boro-phospho silicate glass (BPSG) film, may be a borosilicate glass (BSG) film, may be a phosphosilicate glass (PSG) film, may be an HTO film, or may be a stack of these materials. A thickness of the interlayer dielectric film 38 is, for example, 1.0 μm, but is not limited to this.

The semiconductor apparatus 100 in the present example has a trench contact portion 65 on the front surface 21 side of the semiconductor substrate. The trench contact portion 65 includes a first trench contact 66 and a second trench contact 67.

The trench contact portion 65 is provided on the front surface 21 side of the semiconductor substrate 10 between two adjacent trench portions among the plurality of trench portions. The trench contact portion 65 in the present example is provided extending in the extending direction. The trench contact portion 65 has the contact hole 60 and a metal layer filled in the contact hole 60. An interior of the contact hole 60 may be filled with the same material as that of the emitter electrode 52, or may be filled with a material different from that of the emitter electrode 52. The interior of the contact hole 60 may be filled with tungsten, titanium, titanium alloy, titanium silicide, or the like.

The trench contact portion 65 in the present example is a groove provided in the semiconductor substrate 10 exposed to the contact hole 60. The groove of the trench contact portion 65 may have side walls perpendicular to the front surface 21 in the depth direction, or may have side walls forming a predetermined angle with respect to the front surface 21. The groove of the trench contact portion 65 in the present example is a tapered-shaped groove having the side walls forming the predetermined angle with respect to the front surface 21.

The first trench contact 66 is provided in the diode portion 80 on the front surface 21 side of the semiconductor substrate 10. A depth of the first trench contact 66 may be 0 μm or more and 1.0 μm or less, or may be 0.3 μm or more and 0.4 μm or less.

The second trench contact 67 is provided in the transistor portion 70 on the front surface 21 side of the semiconductor substrate 10. A depth of the second trench contact may be deeper than a depth from the front surface 21 of the semiconductor substrate 10 to a lower end of the emitter region 12. That is, the second trench contact may be provided penetrating the emitter region 12 in the depth direction.

A depth of the second trench contact 67 may be the same as the depth of the first trench contact 66, may be deeper than the depth of the first trench contact 66, or may be shallower than the depth of the first trench contact 66. The depth of the second trench contact 67 in the present example is the same as the depth of the first trench contact 66. If the depth of the first trench contact 66 is the same as the depth of the second trench contact 67, the first trench contact 66 and the second trench contact 67 can be formed by the same process.

The plug contact region 19 is a region of the second conductivity type, which has a higher doping concentration than the base region 14. The plug contact region 19 in the present example is provided on an entire surface below the trench contact portion 65. That is, the plug contact region 19 is provided below both the first trench contact 66 and the second trench contact 67. The plug contact region 19 in the present example is provided in contact with a lower end of the metal layer filled in the trench contact portion 65. A lower end of the plug contact region 19 may 19 may be in contact with the anode region 13 below the first trench contact 66. The lower end of the plug contact region 19 may be in contact with the base region 14 below the second trench contact 67. A depth position of an upper end of the plug contact region 19 may be positioned on the front surface 21 side relative to a bottom surface of the trench contact portion 65 in the depth direction of the semiconductor substrate 10. That is, the plug contact region 19 may be provided so as to cover the bottom surface of the trench contact portion 65.

FIG. 1C shows an example of doping concentration distribution in a cross section b-b′ in FIG. 1B. A position P0 represents a position of the front surface 21 of the semiconductor substrate 10, a position Pt1 represents a depth position of a bottom surface of the first trench contact 66, and a position Pa represents a depth position of a lower end of the anode region 13. The position Pa may be a position where a doping concentration is the same as the doping concentration of the drift region 18.

The anode region 13 in the present example is provided by implanting an ion from the upper surface side of the semiconductor substrate 10. The anode region 13 may be formed through diffusion of the implanted ion. That is, the doping concentration distribution in the anode region 13 may be a distribution in which the doping concentration is gradually decreased from the position P0 of the front surface 21 of the semiconductor substrate 10 to the depth position Pa of the lower end of the anode region 13. It should be noted that the doping concentration distribution in the anode region 13 is not limited to this. The doping concentration distribution in the anode region 13 may be a distribution in which the doping concentration has a peak near a center of the anode region 13, or may be a distribution in which the doping concentration is maximum at the lower end of the anode region 13.

A hole current in the diode portion 80 mainly flows from the bottom surface of the first trench contact 66. That is, a hole is mainly implanted into the anode region 13 from the bottom surface of the first trench contact 66. Accordingly, an operation characteristic of the diode portion 80 may be affected by an integrated amount of the doping concentration for the depth position Pt1 of the bottom surface of the first trench contact 66 to the depth position Pa of the lower end of the anode region 13, which is indicated by a hatched region in FIG. 1C.

Decreasing the integrated amount of the doping concentration for the depth position Pt1 of the bottom surface of the first trench contact 66 to the depth position Pa of the lower end of the anode region 13 decreases an amount of the implanted hole, so that a reverse recovery loss Err of the diode portion 80 can be reduced. Accordingly, deepening the depth position of the bottom surface of the first trench contact 66 and/or decreasing the doping concentration of the anode region 13 decreases the integrated amount of the doping concentration for Pt1 to Pa, so that the reverse recovery loss Err of the diode portion 80 can be reduced. On the other hand, decreasing the integrated amount of the doping concentration for Pt1 to Pa decreases the amount of the implanted hole, so that a forward voltage Vf of the diode portion 80 is increased.

Increasing the integrated amount of the doping concentration for the depth position Pt1 of the bottom surface of the first trench contact 66 to the depth position Pa of the lower end of the anode region 13 increases the amount of the implanted hole, so that the forward voltage Vf of the diode portion 80 can be decreased. Accordingly, shallowing the depth position of the bottom surface of the first trench contact 66 and/or increasing the doping concentration of the anode region 13 increases the integrated amount of the doping concentration for Pt1 to Pa, so that the forward voltage Vf of the diode portion 80 can be decreased. On the other hand, increasing the integrated amount of the doping concentration for Pt1 to Pa increases the amount of the implanted hole, so that the reverse recovery loss Err of the diode portion 80 is increased.

As described above, there is a trade-off relationship between the reverse recovery loss Err of the diode portion 80 and the forward voltage Vf of the diode portion 80. The trade-off relationship between the reverse recovery loss Err of the diode portion 80 and the forward voltage Vf of the diode portion 80 may be controlled by the depth of the first trench contact 66, may be controlled by the doping concentration of the anode region 13, or may be controlled by the depth of the first trench contact 66 and the doping concentration of the anode region 13. In addition, the depth of the first trench contact 66 may be decided according to the doping concentration distribution of the anode region 13, that is, the integrated amount of the doping concentration for Pt1 to Pa.

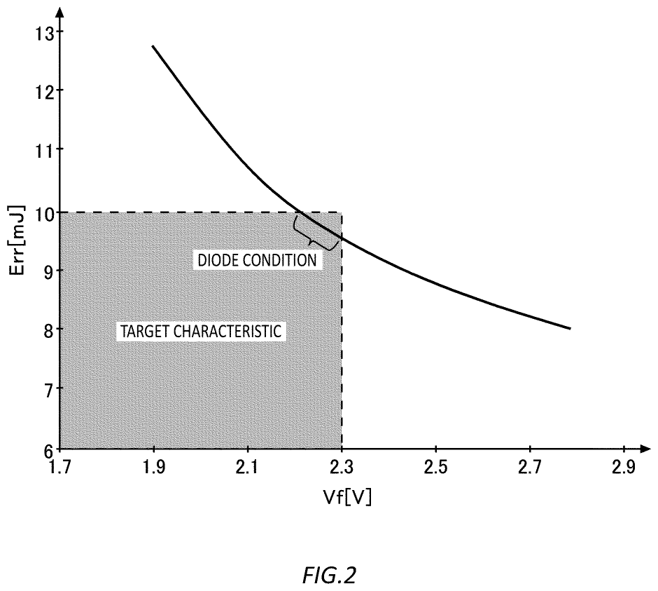

FIG. 2 shows an example of a condition of trade-off between the reverse recovery loss Err of the diode portion 80 and the forward voltage Vf of the diode portion 80. The forward voltage Vf of the diode portion 80 is decreased as the reverse recovery loss Err of the diode portion 80 is increased, and the forward voltage Vf of the diode portion 80 is increased as the reverse recovery loss Err of the diode portion 80 is decreased. The condition of trade-off may be given in a graph format as shown in FIG. 2, may be given in a function expression, or may be given in a numerical data format. The condition of trade-off is not particularly limited as long as it gives a relationship between the reverse recovery loss Err of the diode portion 80 and the forward voltage Vf of the diode portion 80.

A method for manufacturing the semiconductor apparatus 100 may acquire a diode condition which is a condition for realizing a target characteristic, of the condition of trade-off. The target characteristic may be a characteristic required for the semiconductor apparatus 100. As an example, the target characteristic may include a range of the reverse recovery loss Err of the diode portion 80, and may include a lower limit value and/or an upper limit value of the reverse recovery loss Err. As another example, the target characteristic may include a range of the forward voltage Vf of the diode portion 80, and may include a lower limit value and/or an upper limit value of the forward voltage Vf. The target characteristic in the present example has the upper limit value of Err of 10 mJ and the upper limit value of Vf of 2.3V. In the present example, a range from a point where Err is 10 mJ to a point where Vf is 2.3V may be acquired as the diode condition which is the condition for realizing the target characteristic, of the condition of trade-off.

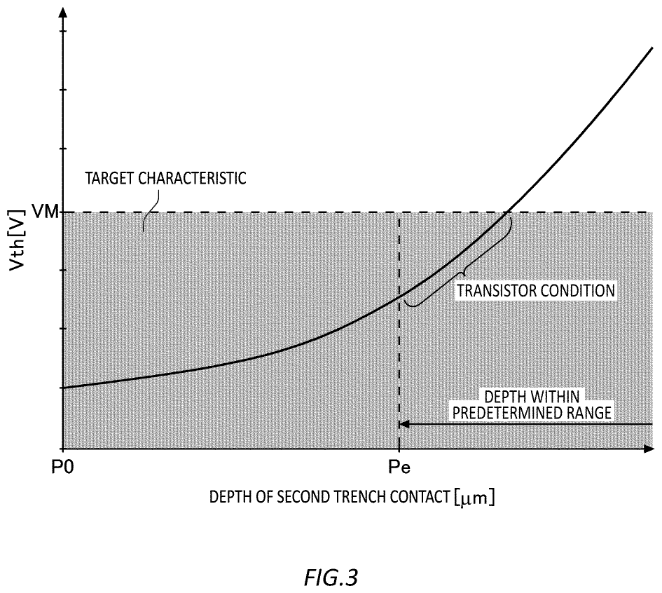

FIG. 3 shows an example of a threshold condition for a threshold voltage Vth of the transistor portion 70 with respect to a depth of the second trench contact 67. The threshold voltage Vth of the transistor portion 70 is monotonously increased with respect to the depth of the second trench contact 67. The threshold condition may be given in a graph format as shown in FIG. 3, may be given in a function expression, or may be given in a numerical data format. The threshold condition is not particularly limited as long as it gives a relationship between the depth of the second trench contact 67 and the threshold voltage Vth of the transistor portion 70.

A method for manufacturing the semiconductor apparatus 100 may acquire a transistor condition which is a condition for realizing a target characteristic, of the threshold condition. As an example, the target characteristic may include a range of the threshold voltage Vth of the transistor portion 70, and may include a lower limit value and/or an upper limit value of the threshold voltage Vth. The target characteristic in the present example has the upper limit value of the threshold voltage Vth of VM. In addition, the transistor condition may include a condition according to the depth of the second trench contact 67 within a predetermined range. That is, the transistor condition may include a range of the depth of the second trench contact 67, and may include a lower limit value and/or an upper limit value of the depth of the second trench contact 67. The transistor condition in the present example includes a condition that the lower limit value of the depth of the second trench contact 67 is Pe. It should be noted that the lower limit depth Pe may be a depth of the emitter region. That is, the depth of the second trench contact 67 may be deeper than a depth from the front surface 21 of the semiconductor substrate 10 to a lower end of the emitter region 12.

As described above, appropriately designing a depth of the first trench contact 66, a doping concentration of the anode region 13, and the depth of the second trench contact 67 can satisfy a diode condition and the transistor condition and realize the target characteristic required for the semiconductor apparatus 100. It should be noted that a relationship between a condition of trade-off, and the depth of the first trench contact 66 and the doping concentration of the anode region 13 will be described later in detail.

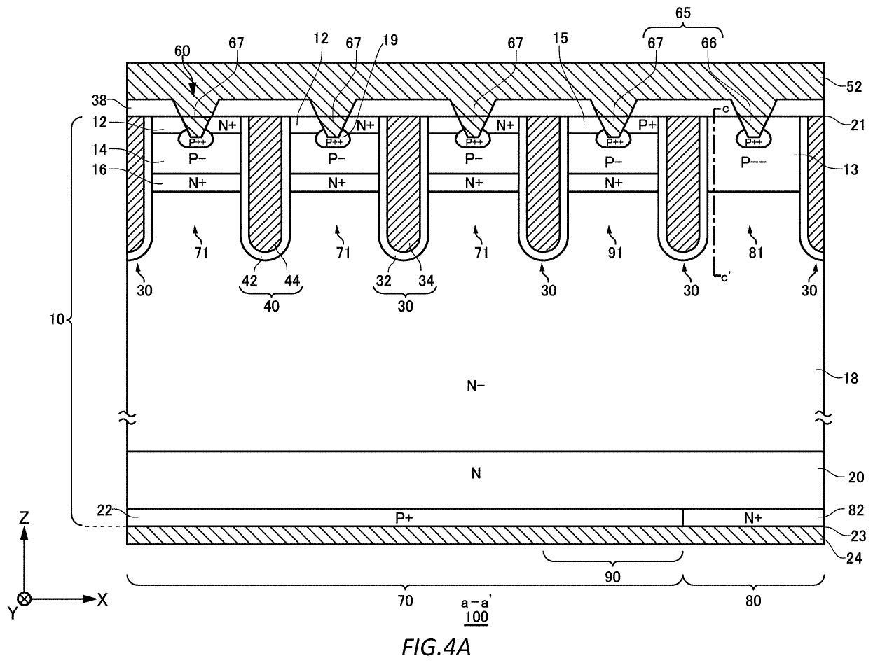

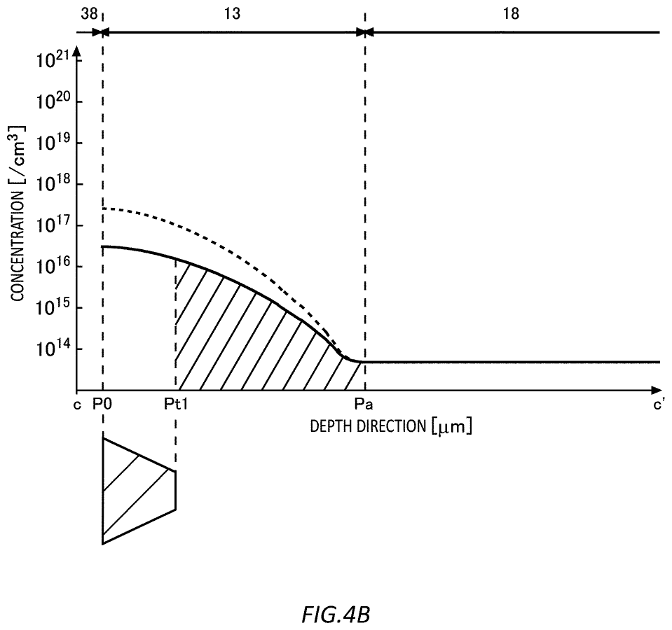

FIG. 4A shows a modified example of the cross section a-a′ in FIG. 1A. The anode region 13 in the present example is of the P−− type, and is different from the example shown in FIG. 1B in that the doping concentration of the anode region 13 is different from the doping concentration of the base region 14. In the present example, a difference from the example shown in FIG. 1B will be particularly described, and others may be the same as in the example shown in FIG. 1B. Decreasing the doping concentration of the anode region 13 can reduce the reverse recovery loss Err of the diode portion 80.

FIG. 4B shows an example of doping concentration distribution in a cross section c-c′ in FIG. 4A. It should be noted that the doping concentration distribution in the example shown in FIG. 1C is indicated by a dotted line. Decreasing the doping concentration of the anode region 13 decreases the integrated amount of the doping concentration for Pt1 to Pa, so that the reverse recovery loss Err of the diode portion 80 can be reduced.

In a method for manufacturing the semiconductor apparatus 100, the transistor portion 70 and the diode portion 80 may have different manufacturing processes in order to satisfy a diode condition and a transistor condition. That is, the doping concentration of the anode region 13 may be different from the doping concentration of the base region 14, and an ion implantation process for forming the anode region 13 may be provided separately from an ion implantation process for forming the base region 14.

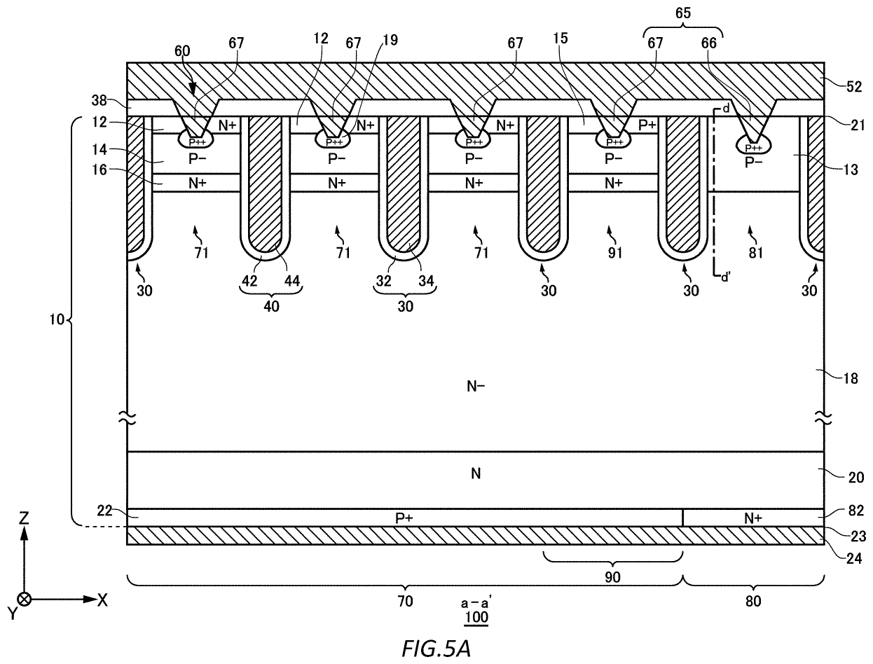

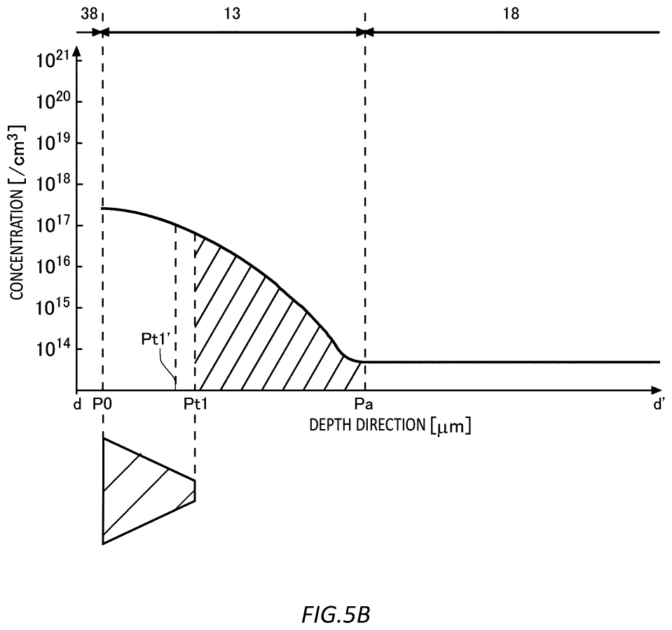

FIG. 5A shows a modified example of the cross section a-a′ in FIG. 1A. The anode region 13 in the present example is of the P-type, but is different from the example shown in FIG. 1B in that a depth of the first trench contact 66 is deeper than a depth of the second trench contact 67. In the present example, a difference from the example shown in FIG. 1B will be particularly described, and others may be the same as in the example shown in FIG. 1B. Increasing the depth of the first trench contact 66 can reduce the reverse recovery loss Err of the diode portion 80.

FIG. 5B shows an example of doping concentration distribution in a cross section d-d′ in FIG. 5A. It should be noted that the depth of the first trench contact 66 in the example shown in FIG. 1C is Pt1′. Increasing the depth of the first trench contact 66 decreases the integrated amount of the doping concentration for Pt1 to Pa, so that the reverse recovery loss Err of the diode portion 80 can be reduced.

In a method for manufacturing the semiconductor apparatus 100, the transistor portion 70 and the diode portion 80 may have different manufacturing processes in order to satisfy a diode condition and a transistor condition. That is, the depth of the first trench contact 66 may be different from the depth of the second trench contact 67, and a formation process of the first trench contact 66 may be provided separately from a formation process of the second trench contact 67.

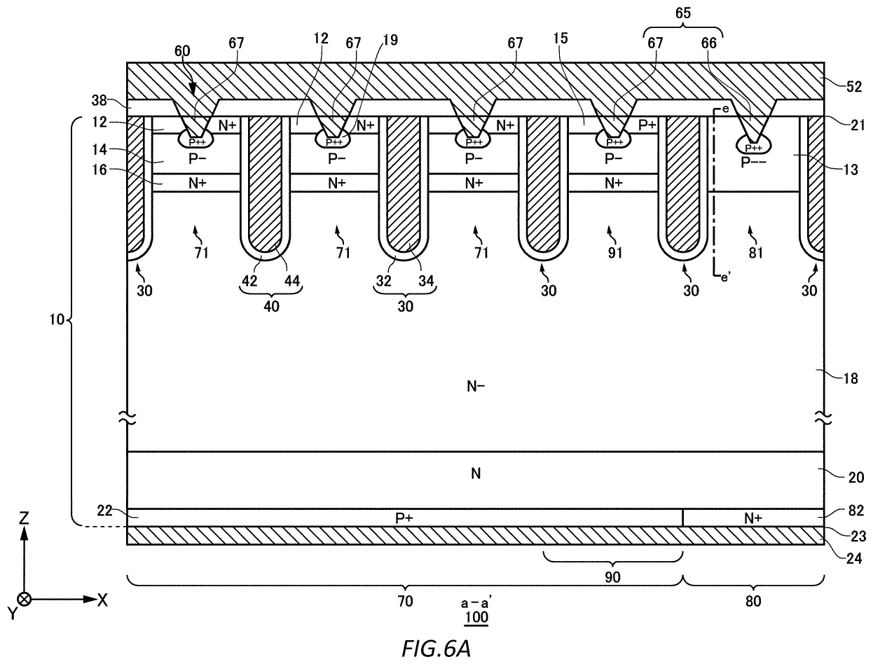

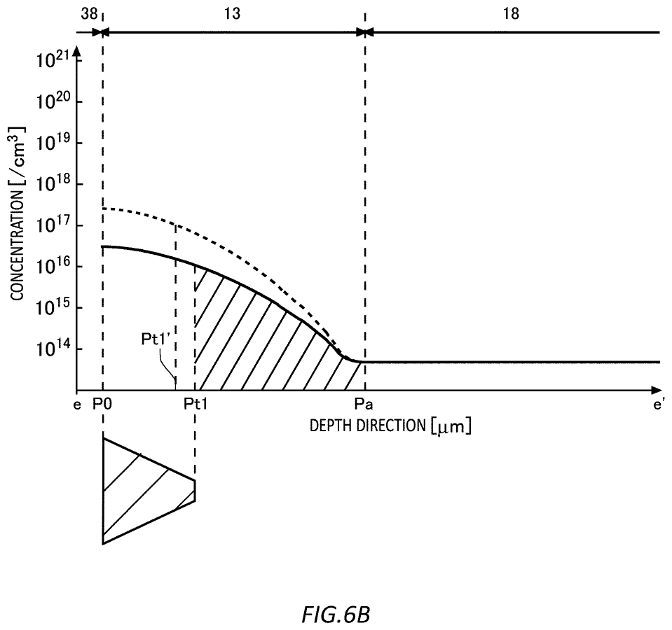

FIG. 6A shows a modified example of the cross section a-a′ in FIG. 1A. The anode region 13 in the present example is of the P−− type, and is different from the example shown in FIG. 1B in that a doping concentration of the anode region 13 is different from the doping concentration of the base region 14 and a depth of the first trench contact 66 is deeper than a depth of the second trench contact 67. In the present example, a difference from the example shown in FIG. 1B will be particularly described, and others may be the same as in the example shown in FIG. 1B. Decreasing the doping concentration of the anode region 13 and increasing the depth of the first trench contact 66 can reduce the reverse recovery loss Err of the diode portion 80.

FIG. 6B shows an example of doping concentration distribution in a cross section e-e′ in FIG. 6A. It should be noted that the doping concentration distribution in the example shown in FIG. 1C is indicated by a dotted line, and the depth of the first trench contact 66 in the example shown in FIG. 1C is Pt1′. Decreasing the doping concentration of the anode region 13 and increasing the depth of the first trench contact 66 decreases the integrated amount of the doping concentration for Pt1 to Pa, so that the reverse recovery loss Err of the diode portion 80 can be reduced.

In a method for manufacturing the semiconductor apparatus 100, the transistor portion 70 and the diode portion 80 may have different manufacturing processes in order to satisfy a diode condition and a transistor condition. That is, the doping concentration of the anode region 13 may be different from the doping concentration of the base region 14, and an ion implantation process for forming the anode region 13 may be provided separately from an ion implantation process for forming the base region 14; and the depth of the first trench contact 66 may be different from the depth of the second trench contact 67, and a formation process of the first trench contact 66 may be provided separately from a formation process of the second trench contact 67.

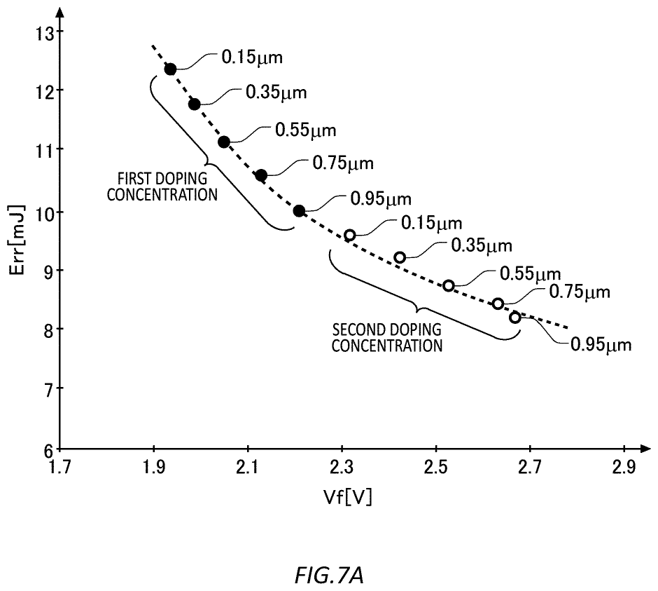

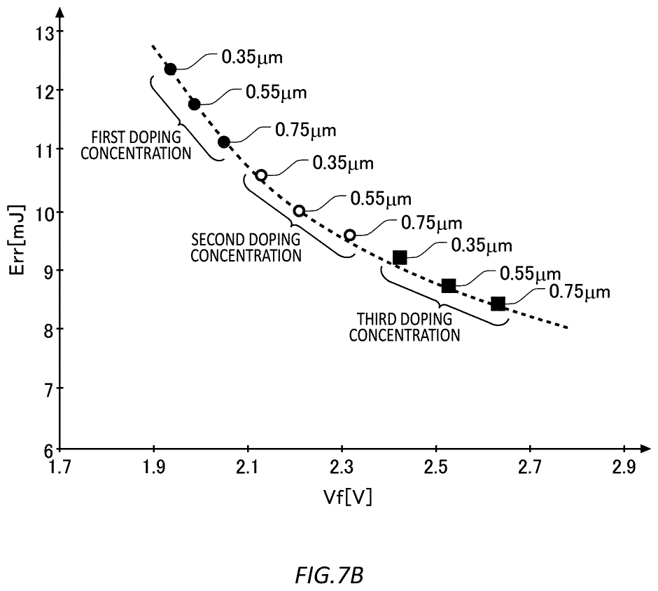

FIG. 7A shows an example of a relationship between a condition of trade-off, and a depth of the first trench contact 66 and a doping concentration of the anode region 13. The condition of trade-off indicated by a dashed line are the same as the condition of trade-off shown in FIG. 2. A black circle represents a first doping concentration, and a white circle represents a second doping concentration. The second doping concentration is lower than the first doping concentration. A numerical value such as 0.15 μm indicated at each point represents the depth of the first trench contact 66.

If the anode region 13 has the same doping concentration (for example, the first doping concentration), the condition of trade-off moves in a direction in which the reverse recovery loss Err of the diode portion 80 is reduced, as the depth of the first trench contact 66 is increased. If the depth of the first trench contact 66 is the same (for example, 0.15 μm), the condition of trade-off moves in the direction in which the reverse recovery loss Err of the diode portion 80 is reduced, as the doping concentration of the anode region 13 is decreased.

In the present example, a range of the condition of trade-off at the first doping concentration do not overlap a range of the condition of trade-off at the second doping concentration, but these ranges may overlap each other. For example, the condition of trade-off for a case where the depth of the first trench contact 66 is 1.05 μm at the first doping concentration may match the condition of trade-off for a case where the depth of the first trench contact 66 is 0.15 μm at the second doping concentration. As another example, the condition of trade-off for a case where the depth of the first trench contact 66 is 0.95 μm at the first doping concentration may match the condition of trade-off for a case where the depth of the first trench contact 66 is 0.05 μm at the second doping concentration. That is, the present example shows only the depth of the first trench contact 66 within a predetermined range. In this manner, a diode condition may include a condition according to the depth of the first trench contact 66 within the predetermined range.

For example, if Vf=2.3V is decided as a target characteristic, the diode condition at the first doping concentration is that the depth of the first trench contact 66 is 1.05 μm. Since the depth of the first trench contact 66 is not included in the predetermined range (0.15 μm to 0.95 μm in the present example), the depth of the first trench contact 66 cannot satisfy the diode condition at the first doping concentration. Therefore, if the diode condition at the second doping concentration is acquired, when the depth of the first trench contact 66 is 0.15 μm, Vf=2.3V can be satisfied, and the depth of the first trench contact 66 is included in the predetermined range, so that setting the depth of the first trench contact 66 to 0.15 μm when the doping concentration of the anode region 13 is the second doping concentration can manufacture the semiconductor apparatus 100 which realizes the target characteristic.

FIG. 7B shows a modified example of a relationship between a condition of trade-off, and a depth of the first trench contact 66 and a doping concentration of the anode region 13. The present example is different from the example shown in FIG. 7A in that the depth of the first trench contact 66 within the predetermined range is 0.35 μm to 0.75 μm and a third doping concentration is included. The second doping concentration is lower than the first doping concentration, and the third doping concentration is lower than the second doping concentration. Similarly to the example shown in FIG. 7A, the doping concentration of the anode region 13 and the depth of the first trench contact 66 for realizing the target characteristic may be designed, in order of the diode condition at the first doping concentration, the diode condition at the second doping concentration, and the diode condition at the third doping concentration.

In the above example, an example has been shown in which the doping concentration is decreased as a number prefixing the doping concentration is increased, but a magnitude relationship of the doping concentration is not limited to this. The doping concentration may be increased as the number prefixing the doping concentration is increased, and the doping concentration may be changed independently of the number prefixing the doping concentration. In addition, in the above example, examples have been shown in which the depth of the first trench contact 66 within the predetermined range is 0.15 μm to 0.95 μm and in which the depth of the first trench contact 66 within the predetermined range is 0.35 μm to 0.75 μm, but the depth of the first trench contact 66 within the predetermined range is not limited to this. The depth of the first trench contact 66 within the predetermined range may be 0 μm or more and 1.0 μm or less, or may be 0.3 μm or more and 0.4 μm or less. Further, the above example has described that after the diode condition at a certain doping concentration is acquired, the depth of the first trench contact 66 at the doping concentration is determined, but after the diode condition at the depth of the first trench contact 66 is acquired, the doping concentration of the anode region 13 at the depth may be determined.

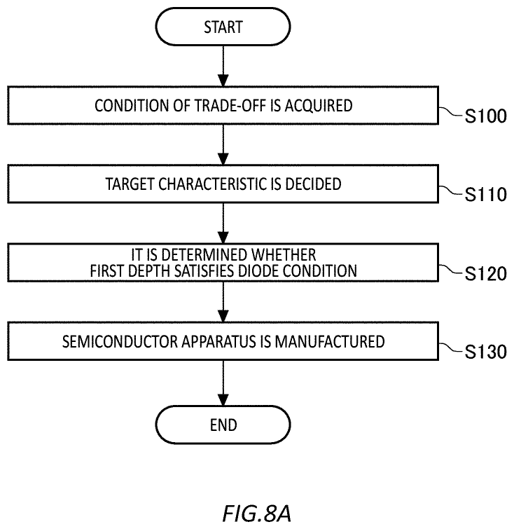

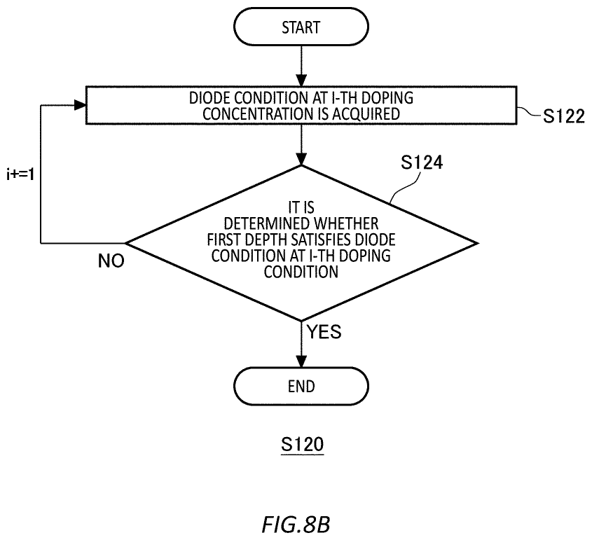

FIG. 8A is a flowchart showing an example of a method for manufacturing the semiconductor apparatus 100. The present example shows the example of the method for manufacturing the semiconductor apparatus 100, and the method is not limited to this.

A step S100 acquires a condition of trade-off between the reverse recovery loss Err of the diode portion 80 and the forward voltage Vf of the diode portion 80. The condition of trade-off may be acquired in advance by experiment, or may be acquired in advance by simulation. The condition of trade-off may be acquired in association with a doping concentration of the anode region 13 and a depth of the first trench contact 66.

A step S110 decides a target characteristic required for the semiconductor apparatus 100. As an example, the target characteristic may include a range of the reverse recovery loss Err of the diode portion 80, and may include a lower limit value and/or an upper limit value of the reverse recovery loss Err. As another example, the target characteristic may include a range of the forward voltage Vf of the diode portion 80, and may include a lower limit value and/or an upper limit value of the forward voltage Vf.

It should be noted that it does not matter which of acquiring the condition of trade-off (S100) and deciding the target characteristic (S110) comes first or later. The condition of trade-off may be acquired after the target characteristic is decided.

A step S120 determines whether a first depth of the first trench contact 66 according to the target characteristic satisfies a diode condition which is a condition for realizing the target characteristic, of the condition of trade-off. The first depth is a depth, which is a design depth of the first trench contact 66 and is to be determined as to whether the diode condition is satisfied. That is, the first depth is not necessarily the depth of the first trench contact 66 in the semiconductor apparatus 100 which is actually manufactured. For example, if S120 determines that the first depth satisfies the diode condition, the semiconductor apparatus 100 may be manufactured in which the depth of the first trench contact 66 is the first depth, and if S120 determines that the first depth does not satisfy the diode condition, the first depth may be changed to a different depth and the doping concentration of the anode region 13 may be changed to a different doping concentration until it is determined that the first depth satisfies the diode condition. An example of the flowchart of S120 will be described later, which includes a case where it is determined that the first depth does not satisfy the diode condition.

As described in association with FIG. 7A and FIG. 7B, the diode condition may include a condition according to the depth of the first trench contact 66 within a predetermined range. In this case, determining whether the first depth satisfies the diode condition (S120) may include determining whether the first depth is included in the predetermined range.

A step S130 manufactures the semiconductor apparatus 100 in which the depth of the first trench contact 66 is the first depth. The first depth may be the first depth determined to satisfy the diode condition. The semiconductor apparatus 100 in which the depth of the first trench contact 66 is the first depth can be manufactured by a method commonly performed by persons skilled in the art. The method for manufacturing the semiconductor apparatus 100 is not limited as long as the manufacturing method can manufacture the semiconductor apparatus 100 in which the depth of the first trench contact 66 is the first depth.

In the method for manufacturing the semiconductor apparatus 100 in the present example, providing the determining whether the first depth of the first trench contact 66 satisfies the diode condition (S120) can effectively manufacture the semiconductor apparatus 100 which realizes a predetermined target characteristic, of the condition of trade-off. That is, the semiconductor apparatus 100 can be manufactured with a higher degree of freedom than a case where the semiconductor apparatus 100 is manufactured which realizes the target characteristic only by adjusting the doping concentration of the anode region 13. In addition, if the depth of the first trench contact 66 is adjusted, it is sufficient to change an etching depth in an etching process, so a design change can be more easily applied than a case where the doping concentration of the anode region 13 is adjusted which requires adjustment of ion implantation energy and a concentration of an ion to be implanted. Further, if the depth of the first trench contact 66 is adjusted, it is possible to avoid a change in an ion implantation apparatus which can be required when the doping concentration of the anode region 13 is adjusted and to reduce manufacturing variability for a case where the doping concentration of the anode region 13 has been decreased.

FIG. 8B is a flowchart showing an example of the step S120 in FIG. 8A. The present example shows an example of the step S120, and the step is not limited to this.

The determining whether the first depth satisfies the diode condition (S120) may include acquiring the diode condition for a case where the doping concentration of the anode region 13 is an i-th doping concentration (S122) and determining whether the first depth satisfies the diode condition at the i-th doping concentration (S124). The i-th doping concentration is a doping concentration, which is a design doping concentration of the doping concentration of the anode region 13 and is to be determined as to whether the diode condition is satisfied. That is, the i-th doping concentration is not necessarily the doping concentration of the anode region 13 in the semiconductor apparatus 100 which is actually manufactured. For example, if S124 determines that the first depth satisfies the diode condition at the i-th doping concentration acquired in S122, the semiconductor apparatus 100 may be manufactured in which the doping concentration of the anode region 13 is the i-th doping concentration, and if S124 determines that the first depth does not satisfy the diode condition at the i-th doping concentration, the doping concentration of the anode region 13 may be changed to a different doping concentration until it is determined that the first depth satisfies the diode condition. That is, S122 and S124 may be repetitively performed until S124 determines that the first depth satisfies the diode condition at the i-th doping concentration.

More specifically, the determining whether the first depth satisfies the diode condition (S120) may include acquiring the diode condition for a case where the doping concentration of the anode region 13 is a first doping concentration and determining whether the first depth satisfies the diode condition at the first doping concentration. As an example, the first doping concentration is a doping concentration of the base region 14. If the doping concentration of the anode region 13 is the same as the doping concentration of the base region 14, the anode region 13 and the base region 14 can be formed by the same ion implantation process. Accordingly, adopting the doping concentration of the base region 14 as the first doping concentration can preferentially design the semiconductor apparatus 100 which can form the anode region 13 and the base region 14 by the same ion implantation process.

If the first depth satisfies the diode condition at the first doping concentration, manufacturing the semiconductor apparatus 100 (S130) may include manufacturing the semiconductor apparatus 100 in which the depth of the first trench contact 66 is the first depth. That is, if S124 determines that the first depth satisfies the diode condition at the first doping concentration, S120 shown in FIG. 8B may end, the process may proceed to the manufacturing the semiconductor apparatus 100 in which the depth of the first trench contact 66 is the first depth (S130) in FIG. 8A, and the semiconductor apparatus 100 may be manufactured in which the depth of the first trench contact 66 is the first depth determined to satisfy the diode condition.

If the first depth does not satisfy the diode condition at the first doping concentration, the determining whether the first depth satisfies the diode condition (S120) may include the acquiring the diode condition for a case where the doping concentration of the anode region 13 is a second doping concentration lower than the first doping concentration (S122) and the determining whether the first depth satisfies the diode condition at the second doping concentration (S124). That is, if S124 determines that the first depth does not satisfy the diode condition at the first doping concentration, the process may return to S122, the diode condition at the second doping concentration which is a doping concentration different from the first doping concentration may be acquired, the process may proceed to S124 again, and it may be determined whether the first depth satisfies the diode condition at the second doping concentration.

The second doping concentration may be lower than the first doping concentration, or may be higher than the first doping concentration. The second doping concentration in the present example is lower than the first doping concentration. Decreasing the doping concentration of the anode region 13 decreases the reverse recovery loss Err of the diode portion 80, and increasing the doping concentration of the anode region 13 increases the reverse recovery loss Err of the diode portion 80. In addition, decreasing the doping concentration of the anode region 13 increases the forward voltage Vf of the diode portion 80, and increasing the doping concentration of the anode region 13 decreases the forward voltage Vf of the diode portion 80. Accordingly, if the first depth does not satisfy the diode condition at the first doping concentration and if the reverse recovery loss Err of the diode portion 80 at the first depth exceeds the reverse recovery loss Err which is the target characteristic, the second doping concentration may be set lower than the first doping concentration, and if the forward voltage Vf of the diode portion 80 at the first depth exceeds the forward voltage Vf which is the target characteristic, the second doping concentration may be set higher than the first doping concentration.

If the first depth satisfies the diode condition at the second doping concentration, the manufacturing the semiconductor apparatus 100 (S130) may include manufacturing the semiconductor apparatus 100 in which the depth of the first trench contact 66 is the first depth. That is, if S124 determines that the first depth satisfies the diode condition at the second doping concentration, S120 shown in FIG. 8B may end, the process may proceed to the manufacturing the semiconductor apparatus 100 in which the depth of the first trench contact 66 is the first depth (S130) in FIG. 8A, and the semiconductor apparatus 100 may be manufactured in which the depth of the first trench contact 66 is the first depth determined to satisfy the diode condition.

If the first depth does not satisfy the diode condition at the second doping concentration, the determining whether the first depth satisfies the diode condition (S120) may include the acquiring the diode condition for a case where the doping concentration of the anode region 13 is a third doping concentration lower than the second doping concentration (S122) and the determining whether the first depth satisfies the diode condition at the third doping concentration (S124). That is, if S124 determines that the first depth does not satisfy the diode condition at the second doping concentration, the process may return to S122, the diode condition at the third doping concentration which is a doping concentration different from the second doping concentration may be acquired, the process may proceed to S124 again, and it may be determined whether the first depth satisfies the diode condition at the third doping concentration. The third doping concentration may be lower than the second doping concentration, or may be higher than the second doping concentration. The third doping concentration in the present example is lower than the second doping concentration.

As described above, S122 and S124 may be repetitively performed until S124 determines that the first depth satisfies the diode condition at the i-th doping concentration. In the above example, the steps have been described up to acquiring the diode condition at the third doping concentration and performing determination, but the steps may be repetitively performed until it is determined that the first depth satisfies the diode condition at a fourth doping concentration, a fifth doping concentration, . . . , and the i-th doping concentration, similarly. In addition, in the above example, an example has been shown in which the doping concentration is decreased as a number prefixing the doping concentration is increased, but a magnitude relationship of the doping concentration is not limited to this. The doping concentration may be increased as the number prefixing the doping concentration is increased, and the doping concentration may be changed independently of the number prefixing the doping concentration. Further, the above example has described that after the diode condition at the i-th doping concentration is acquired, the depth of the first trench contact 66 at the doping concentration is determined, but after the diode condition at the depth of the first trench contact 66 is acquired, the doping concentration of the anode region 13 at the depth may be determined.

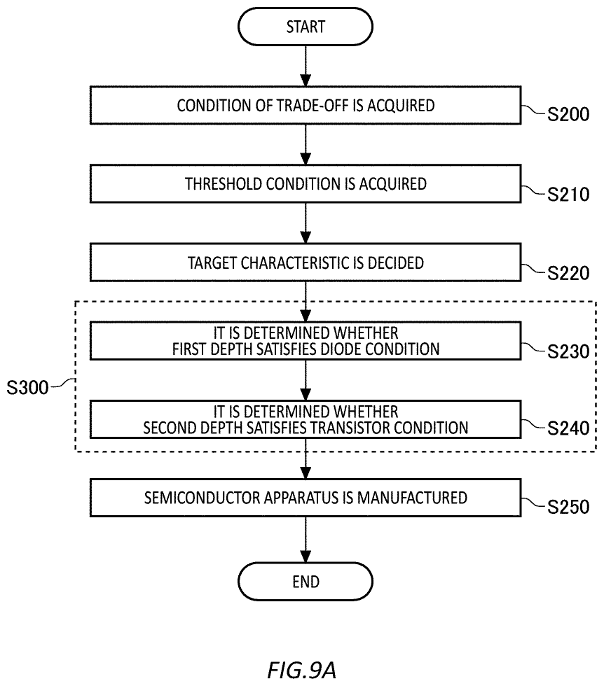

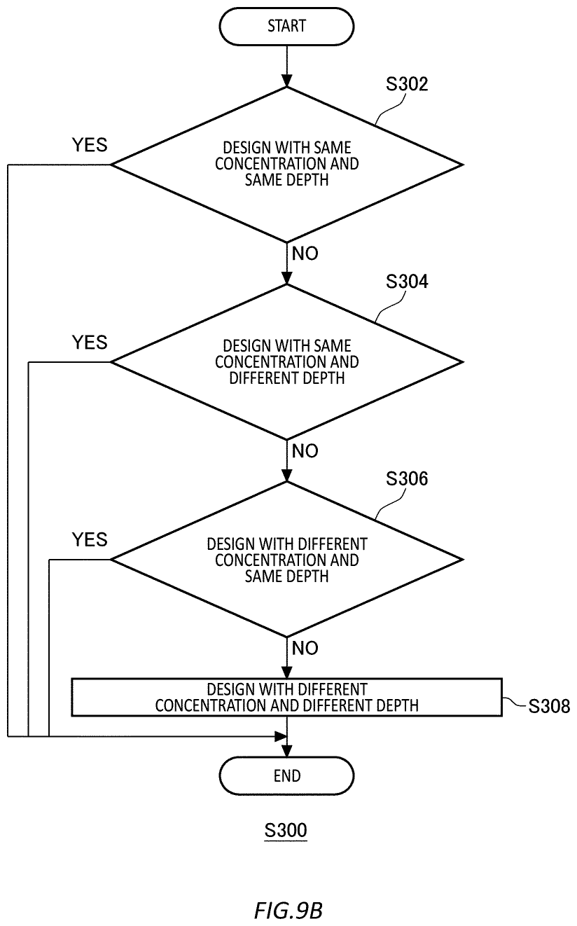

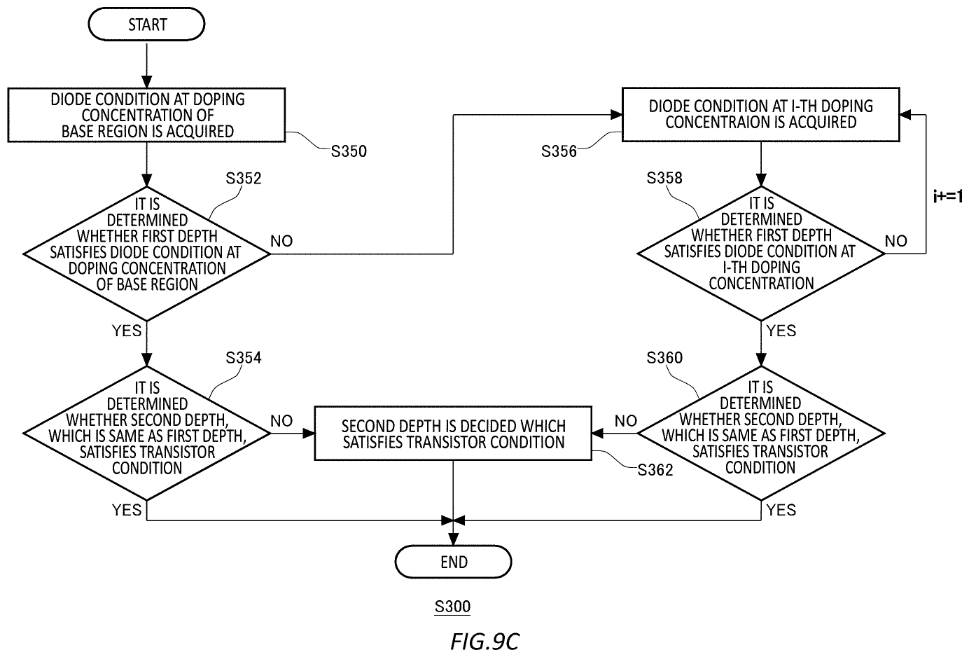

FIG. 9A is flowchart showing a modified example of a method for manufacturing the semiconductor apparatus 100. The flowchart in the present example is different from the example shown in FIG. 8A in that it considers a transistor condition together with a diode condition. In the present example, a difference from the example shown in FIG. 8A will be particularly described, and others may be the same as in the example shown in FIG. 8A.

A step S210 acquires a threshold condition indicating a relationship between a depth of the second trench contact 67 and the threshold voltage Vth of the transistor portion 70. The threshold condition may be acquired in advance by experiment, or may be acquired in advance by simulation. It should be noted that it does not matter in which order the following steps are performed: acquiring a condition of trade-off (S200); acquiring the threshold condition (S210); and deciding a target characteristic (S220).

A step S240 determines whether a second depth of the second trench contact 67 according to the target characteristic satisfies the transistor condition which is a condition for satisfying the target characteristic, of the threshold condition. The second depth is a depth, which is a design depth of the second trench contact 67 and is to be determined as to whether the transistor condition is satisfied. That is, the second depth is not necessarily the depth of the second trench contact 67 in the semiconductor apparatus 100 which is actually manufactured. For example, if S240 determines that the second depth satisfies the transistor condition, the semiconductor apparatus 100 may be manufactured in which the depth of the second trench contact 67 is the second depth.

It does not matter which of determining whether the first depth satisfies the diode condition (S230) and determining whether the second depth satisfies the transistor condition (S240) comes first or later. It may be determined whether the first depth satisfies the diode condition after it is determined whether the second depth satisfies the transistor condition, or it may be determined whether the second depth satisfies the transistor condition at the same time as it is determined whether the first depth satisfies the diode condition. Performing a combination (S300) of the determining whether the first depth satisfies the diode condition (S230) and the determining whether the second depth satisfies the transistor condition (S240) will be described later.

Manufacturing the semiconductor apparatus (S250) may include manufacturing the semiconductor apparatus 100 in which the depth of the second trench contact 67 is the second depth. That is, the manufacturing the semiconductor apparatus (S250) may include manufacturing the semiconductor apparatus 100 in which the depth of the first trench contact 66 is the first depth similarly to the manufacturing the semiconductor apparatus (S130) in FIG. 8A, and may include manufacturing the semiconductor apparatus 100 in which the depth of the second trench contact 67 is the second depth.

FIG. 9B is a flowchart showing an example of the step S300 in FIG. 9A. The present example shows an example of the step S300, and the step is not limited to this.

A step S302 performs a design in which a doping concentration of the anode region 13 is the same doping concentration as a doping concentration of the base region 14 and the depth of the first trench contact 66 is the same as the depth of the second trench contact 67. That is, the determining whether the first depth satisfies the diode condition (S230) may include acquiring the diode condition for a case where the doping concentration of the anode region 13 is the doping concentration of the base region 14 and determining whether the first depth satisfies the diode condition at the doping concentration of the base region 14, the determining whether the second depth satisfies the transistor condition (S240) may include determining whether the second depth, which is the same as the first depth, satisfies the transistor condition.

If the doping concentration of the anode region 13 is the same as the doping concentration of the base region 14, the anode region 13 and the base region 14 can be formed by the same ion implantation process. In addition, if the depth of the first trench contact 66 is the same as the depth of the second trench contact 67, the first trench contact 66 and the second trench contact 67 can be manufactured by the same process.

A step S304 performs a design in which the doping concentration of the anode region 13 is the same doping concentration as the doping concentration of the base region 14 and the depth of the first trench contact 66 is different from the depth of the second trench contact 67. That is, the determining whether the first depth satisfies the diode condition (S230) may include acquiring the diode condition for a case where the doping concentration of the anode region 13 is the doping concentration of the base region 14 and determining whether the first depth satisfies the diode condition at the doping concentration of the base region 14, the determining whether the second depth satisfies the transistor condition (S240) may include determining whether the second depth, which is different from the first depth, satisfies the transistor condition.

If the doping concentration of the anode region 13 is the same as the doping concentration of the base region 14, the anode region 13 and the base region 14 can be formed by the same ion implantation process.

A step S306 performs a design in which the doping concentration of the anode region 13 is a doping concentration different from the doping concentration of the base region 14 and the depth of the first trench contact 66 is the same as the depth of the second trench contact 67. That is, the determining whether the first depth satisfies the diode condition (S230) may include acquiring the diode condition for a case where the doping concentration of the anode region 13 is the first doping concentration different from the doping concentration of the base region 14 and determining whether the first depth satisfies the diode condition at the first doping concentration, the determining whether the second depth satisfies the transistor condition (S240) may include determining whether the second depth, which is the same as the first depth, satisfies the transistor condition.

If the depth of the first trench contact 66 is the same as the depth of the second trench contact 67, the first trench contact 66 and the second trench contact 67 can be manufactured by the same process.

A step S308 performs a design in which the doping concentration of the anode region 13 is a doping concentration different from the doping concentration of the base region 14 and the depth of the first trench contact 66 is different from the depth of the second trench contact 67. That is, the determining whether the first depth satisfies the diode condition (S230) may include acquiring the diode condition for a case where the doping concentration of the anode region 13 is the first doping concentration different from the doping concentration of the base region 14 and determining whether the first depth satisfies the diode condition at the first doping concentration, the determining whether the second depth satisfies the transistor condition (S240) may include determining whether the second depth, which is different from the first depth, satisfies the transistor condition.

The order of the step S302 to the step S308 is not limited to this. As an example, the step S306 may be performed before the step S304. The design in the step 302 may be performed prior to the other steps because it is the most efficient manufacturing method by which an ion implantation process and a trench contact formation process can be the same.

FIG. 9C is a flowchart showing a modified example of the step S300 in FIG. 9A. The flowchart in the present example may be an example more specifically showing the flowchart in FIG. 9B.

A step S350 acquires the diode condition for a case where the doping concentration of the anode region 13 is the doping concentration of the base region 14, and a step S352 determines whether the first depth satisfies the diode condition at the doping concentration of the base region 14. The step S350 and the step S352 may correspond to the step S302 and/or the step S304, and impose a condition that the doping concentration of the anode region 13 is the same doping concentration as the doping concentration of the base region 14.

If the first depth satisfies the diode condition at the doping concentration of the base region 14 (YES), the condition can be satisfied that the doping concentration of the anode region 13 is the same doping concentration as the doping concentration of the base region 14, so the process proceeds to a step 354. If the first depth does not satisfy the diode condition at the doping concentration of the base region 14 (NO), the condition cannot be satisfied that the doping concentration of the anode region 13 is the same doping concentration as the doping concentration of the base region 14, so the process proceeds to a step 356.

A step S354 determines whether the second depth, which is the same as the first depth, satisfies the transistor condition. The step S354 may correspond to the step S302, and impose a condition that the depth of the first trench contact 66 is the same as the depth of the second trench contact 67.

If the second depth, which is the same as the first depth, satisfies the transistor condition (YES), the design is completed in which the doping concentration of the anode region 13 is the same doping concentration as the doping concentration of the base region 14 and the depth of the first trench contact 66 is the same as the depth of the second trench contact 67, and the step S300 ends. If the second depth, which is the same as the first depth, does not satisfy the transistor condition (NO), the condition cannot be satisfied that the depth of the first trench contact 66 is the same as the depth of the second trench contact 67, so the process proceeds to a step S362.

A step S356 acquires the diode condition for a case where the doping concentration of the anode region 13 is an i-th doping concentration different from the doping concentration of the base region 14, and a step S358 determines whether the first depth satisfies the diode condition at the i-th doping concentration. The step S356 and the step S358 may correspond to the step S306 and/or the step S308, and impose a condition that the doping concentration of the anode region 13 is a doping concentration different from the doping concentration of the base region 14. The step S356 and the step S358 may respectively correspond to the step S122 and the step S124 in FIG. 8B, and may be repetitively performed. If the first depth satisfies the diode condition at the i-th doping concentration (YES) as a result of the step S356 and the step S358 being performed once or repetitively, the process proceeds to a step S360.

The step S360 determines whether the second depth, which is the same as the first depth, satisfies the transistor condition. The step S360 may correspond to the step S306, and impose a condition that the depth of the first trench contact 66 is the same as the depth of the second trench contact.

If the second depth, which is the same as the first depth, satisfies the transistor condition (YES), the design is completed in which the doping concentration of the anode region 13 is a doping concentration different from the doping concentration of the base region 14 and the depth of the first trench contact 66 is the same as the depth of the second trench contact 67, and the step S300 ends. If the second depth, which is the same as the first depth, does not satisfy the transistor condition (NO), the condition cannot be satisfied that the depth of the first trench contact 66 is the same as the depth of the second trench contact 67, so the process proceeds to the step S362.

The step 362 decides the second depth which satisfies the transistor condition. The transistor condition is a condition which constrains only the depth of the second trench contact 67 via the threshold condition. That is, if there is no condition that the second depth is the same as the first depth and the second depth can be independently decided, there may always be the second depth which satisfies the transistor condition. The step S362 may correspond to the step S304 and/or the step S308, and satisfy a condition that the depth of the first trench contact 66 is different from the depth of the second trench contact 67.

As described above, according to the flowchart in the present example, any one of the designs in the flowchart in FIG. 9B can be produced. It should be noted that the flowchart in the present example shows an example of the step S300, and the step is not limited to this.

While the present invention has been described above using embodiments, a technical scope of the present invention is not limited to a scope described in the above-described embodiments. It is apparent to persons skilled in the art that various alterations or improvements can be made to the above-described embodiment. It is also apparent from description of the claims that the embodiments to which such alterations or improvements are made can be included in the technical scope of the present invention.

It should be noted that the operations, procedures, steps, stages, and the like of each processing performed by an apparatus, system, program, and method shown in the claims, specification, or drawings can be realized in any order as long as the order is not indicated by “prior to,” “before,” or the like and as long as the output from a previous processing is not used in a later processing. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate, 12: emitter region, 13: anode region, 14: base region, 15: contact region, 16: accumulation region, 17: well region, 18: drift region, 19: plug contact region, 20: buffer region, 21: front surface, 22: collector region, 23: back surface, 24: collector electrode, 25: connection portion, 30: dummy trench portion, 31: extending part, 32: dummy dielectric film, 33: connecting part, 34: dummy conductive portion, 38: interlayer dielectric film, 40: gate trench portion, 41: extending part, 42: gate dielectric film, 43: connecting part, 44: gate conductive portion, 50: gate metal layer, 52: emitter electrode, 55: contact hole, 56: contact hole, 60: contact hole, 65: trench contact portion, 66: first trench contact, 67: second trench contact, 70: transistor portion, 71: mesa portion, 80: diode portion, 81: mesa portion, 82: cathode region, 90: intermediate region, 91: mesa portion, 100: semiconductor apparatus.

What is claimed is:

1. A method for manufacturing a semiconductor apparatus including: a transistor portion provided in a semiconductor substrate of a first conductivity type and including a base region of a second conductivity type; a diode portion provided in the semiconductor substrate and including an anode region of the second conductivity type; and a first trench contact provided in the diode portion on a front surface side of the semiconductor substrate, the method comprising:
acquiring a condition of trade-off between a reverse recovery loss of the diode portion and a forward voltage of the diode portion;
deciding a target characteristic required for the semiconductor apparatus;
determining whether a first depth of the first trench contact according to the target characteristic satisfies a diode condition which is a condition for realizing the target characteristic, of the condition of trade-off; and
manufacturing the semiconductor apparatus in which a depth of the first trench contact is the first depth.

2. The method for manufacturing a semiconductor apparatus according to claim 1, wherein
the determining whether the first depth satisfies the diode condition includes:
acquiring the diode condition for a case where a doping concentration of the anode region is a first doping concentration; and
determining whether the first depth satisfies the diode condition at the first doping concentration.

3. The method for manufacturing a semiconductor apparatus according to claim 2, wherein
the first doping concentration is a doping concentration of the base region.

4. The method for manufacturing a semiconductor apparatus according to claim 2, wherein
if the first depth satisfies the diode condition at the first doping concentration,
the manufacturing the semiconductor apparatus includes manufacturing the semiconductor apparatus in which the depth of the first trench contact is the first depth, and
if the first depth does not satisfy the diode condition at the first doping concentration,
the determining whether the first depth satisfies the diode condition includes:
acquiring the diode condition for a case where the doping concentration of the anode region is a second doping concentration lower than the first doping concentration; and
determining whether the first depth satisfies the diode condition at the second doping concentration.

5. The method for manufacturing a semiconductor apparatus according to claim 4, wherein
if the first depth satisfies the diode condition at the second doping concentration,
the manufacturing the semiconductor apparatus includes manufacturing the semiconductor apparatus in which the depth of the first trench contact is the first depth, and
if the first depth does not satisfy the diode condition at the second doping concentration,
the determining whether the first depth satisfies the diode condition includes:
acquiring the diode condition for a case where the doping concentration of the anode region is a third doping concentration lower than the second doping concentration; and
determining whether the first depth satisfies the diode condition at the third doping concentration.

6. The method for manufacturing a semiconductor apparatus according to claim 1, wherein
the semiconductor apparatus includes a second trench contact provided in the transistor portion on the front surface side of the semiconductor substrate,
the method comprising:
acquiring a threshold condition indicating a relationship between a depth of the second trench contact and a threshold voltage of the transistor portion; and
determining whether a second depth of the second trench contact according to the target characteristic satisfies a transistor condition which is a condition for realizing the target characteristic, of the threshold condition, and
the manufacturing the semiconductor apparatus includes manufacturing the semiconductor apparatus in which the depth of the second trench contact is the second depth.

7. The method for manufacturing a semiconductor apparatus according to claim 6, wherein
the determining whether the first depth satisfies the diode condition includes:
acquiring the diode condition for a case where a doping concentration of the anode region is a doping concentration of the base region; and
determining whether the first depth satisfies the diode condition at the doping concentration of the base region.

8. The method for manufacturing a semiconductor apparatus according to claim 7, wherein
the determining whether the second depth satisfies the transistor condition includes determining whether the second depth, which is a same as the first depth, satisfies the transistor condition.

9. The method for manufacturing a semiconductor apparatus according to claim 6, wherein
the determining whether the first depth satisfies the diode condition includes:
acquiring the diode condition for a case where a doping concentration of the anode region is a first doping concentration different from a doping concentration of the base region; and
determining whether the first depth satisfies the diode condition at the first doping concentration.

10. The method for manufacturing a semiconductor apparatus according to claim 9, wherein
the determining whether the second depth satisfies the transistor condition includes determining whether the second depth, which is a same as the first depth, satisfies the transistor condition.

11. The method for manufacturing a semiconductor apparatus according to claim 1, wherein
the diode condition includes a condition according to the depth of the first trench contact within a predetermined range,
the determining whether the first depth satisfies the diode condition includes determining whether the first depth is included in the predetermined range.

12. The method for manufacturing a semiconductor apparatus according to claim 2, wherein
the diode condition includes a condition according to the depth of the first trench contact within a predetermined range,
the determining whether the first depth satisfies the diode condition includes determining whether the first depth is included in the predetermined range.

13. The method for manufacturing a semiconductor apparatus according to claim 3, wherein
the diode condition includes a condition according to the depth of the first trench contact within a predetermined range,
the determining whether the first depth satisfies the diode condition includes determining whether the first depth is included in the predetermined range.

14. The method for manufacturing a semiconductor apparatus according to claim 4, wherein
the diode condition includes a condition according to the depth of the first trench contact within a predetermined range,
the determining whether the first depth satisfies the diode condition includes determining whether the first depth is included in the predetermined range.

15. The method for manufacturing a semiconductor apparatus according to claim 1, wherein
the first depth is 0 μm or more and 1.0 μm or less.

16. The method for manufacturing a semiconductor apparatus according to claim 1, wherein
the first depth is 0.3 μm or more and 0.4 μm or less.

17. The method for manufacturing a semiconductor apparatus according to claim 1, wherein
a doping concentration of the anode region is 1e12/cm² or higher and 1e14/cm² or lower.

18. The method for manufacturing a semiconductor apparatus according to claim 1, wherein
the semiconductor apparatus includes a plug contact region of the second conductivity type provided below the first trench contact and having a higher doping concentration than the base region.

19. The method for manufacturing a semiconductor apparatus according to claim 6, wherein
the semiconductor apparatus includes an emitter region of the first conductivity type provided above the base region, and
the second depth is deeper than a depth from the front surface of the semiconductor substrate to a lower end of the emitter region.

20. The method for manufacturing a semiconductor apparatus according to claim 6, wherein
the semiconductor apparatus includes a plug contact region of the second conductivity type provided below the first trench contact and the second trench contact and having a higher doping concentration than the base region.
